(19) United States
(12) Patent Application Publication
(10) Pub. No.: US 2007/0071592 A1
(43) Pub. Date: Mar. 29, 2007

(54) Temperature Control Device of Simple Cooling Fan

(76) Inventor: Train Lin, Taipei City (TW)

Correspondence Address: HDSL, 4331 STEVENS BATTLE LANE, FAIRFAX, VA, 22033, US

(21) Appl. No.: 11/458,154

(22) Filed: Jul. 18, 2006

(30) Foreign Application Priority Data
Sep. 23, 2005 (TW) 094216429

(51) Int. Cl. F04D 15/00; H05K 7/20

(52) U.S. Cl. 415/47; 361/695

(57) ABSTRACT

A temperature control device of a simple cooling fan includes a fan motor, a driver device, and a temperature control device. The driver device is electrically connected to the fan motor. The temperature control device is electrically connected to the fan motor and the driver device. The driver device detects the temperature rise variation of the electronic element and drives the fan motor to rotate in high speed. When the fan motor remains in high rotational speed as the temperature of the electronic element decreases, a voltage-drop signal is generated to drive the fan motor to its reduce rotational speed. The temperature control device achieves control abilities similar to that of a MCU, reduces manufacturing costs, and reduces over all physical size of the cooling fan, and is suitable for use in compact electronics.

### BACKGROUND OF THE INVENTION

1. Field of the Invention

The present invention relates to a cooling device, and in particular, to a simple temperature control device of a cooling fan.

2. Description of Prior Art

Current focus in the IT and consumer electronics industry is on the development of electronic gadgetries with multi-functions, high computational power, and compact size. Due to high density and high computation power of electronic components, a lot of heat is generated during device operation. A cooling mechanism is therefore required to prevent overheat and enable proper circuit operation. The cooling fan plays a major role in a cooling mechanism in generating sufficient wind flow to increase heat exchange rates, thereby accomplishing fast heat dissipation.

FIG. 1 shows schematic illustrating the architecture of a traditional cooling fan 1, which includes a fan motor 11, and a fan driver device 12 for controlling operation of fan motor 11. Fan driver device 12 includes either a driver IC or a MCU (Micro-Controller Unit), a Hall element, and a temperature sensor. The Hall element and the temperature sensor detect the temperature variation of the electronic element, and the driver IC or the MCU triggers fan motor 11 to generate rotation or adjust fan rotational speed based on temperature variation.

However, the traditional temperature-controlled speed adjustment design of cooling fans are physically limited in size due to the structural nature of the electronic elements and wires, and can not be reduced to less than 6 cm. Hence, the traditional model does not satisfy the current design trend for lightweight and compact electronics. Also, the servo control of traditional cooling fan does not reach a fast, stable, and flawless state. Although the use of a MCU may solve such a problem, the implementation of a MCU means a 2 to 3 times increase in costs as compared to a traditional architecture, and works in no favor to bring down the manufacturing size to less than 6 cm.

### SUMMARY OF THE INVENTION

It is therefore an object of the invention to solve the afore-mentioned problems. The invention utilizes the simple design of a temperature control device, which is directly attached externally to a cooling fan motor, for detecting the temperature variation of an electronic element so as to control voltage drops and reduce rotational speeds of the fan motor.

In addition to achieving the control abilities similar to that of a MCU in low costs, the temperature control device of a cooling fan also reduces the overall physical size, thus suitable for use in compact electronic devices.

The invention achieves the above object by providing a temperature control device of a simple cooling fan that includes a fan motor, a driver device, and a temperature control device. The driver device is connected to the fan motor. The temperature control device is connected to both the fan motor and the driver device. The temperature control device detects the temperature variation of the electronic element and generates a voltage-drop signal to drive the fan motor in reducing rotational speed.

### BRIEF DESCRIPTION OF THE DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is circuit schematic illustrating the architecture of a traditional cooling fan;

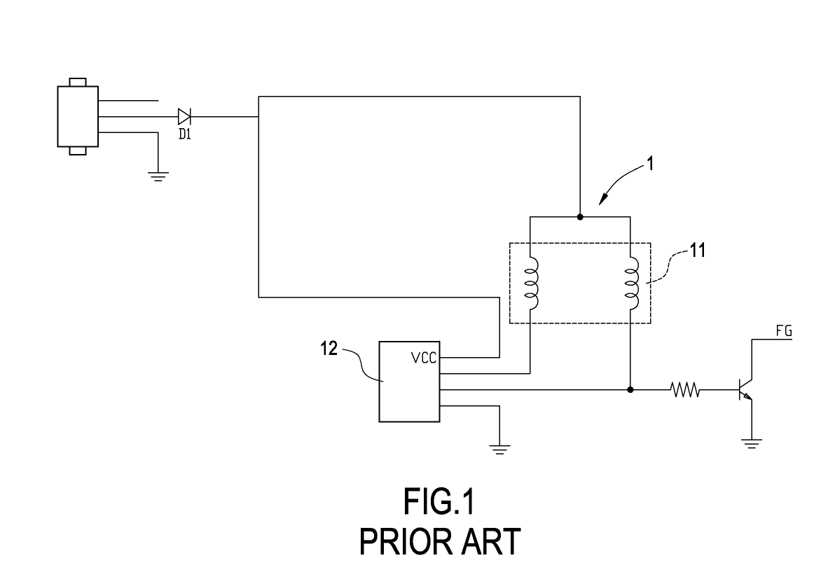

FIG. 2 is block diagram illustrating a temperature control device according to a preferred embodiment of the invention;

FIG. 3 is a circuit schematic illustrating a temperature control device according to a preferred embodiment of the invention; and

FIG. 4 is circuit schematic illustrating a temperature control device according to another preferred embodiment of the invention.

### DETAILED DESCRIPTION OF THE INVENTION

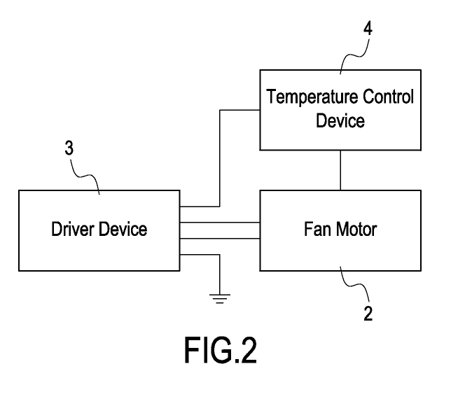

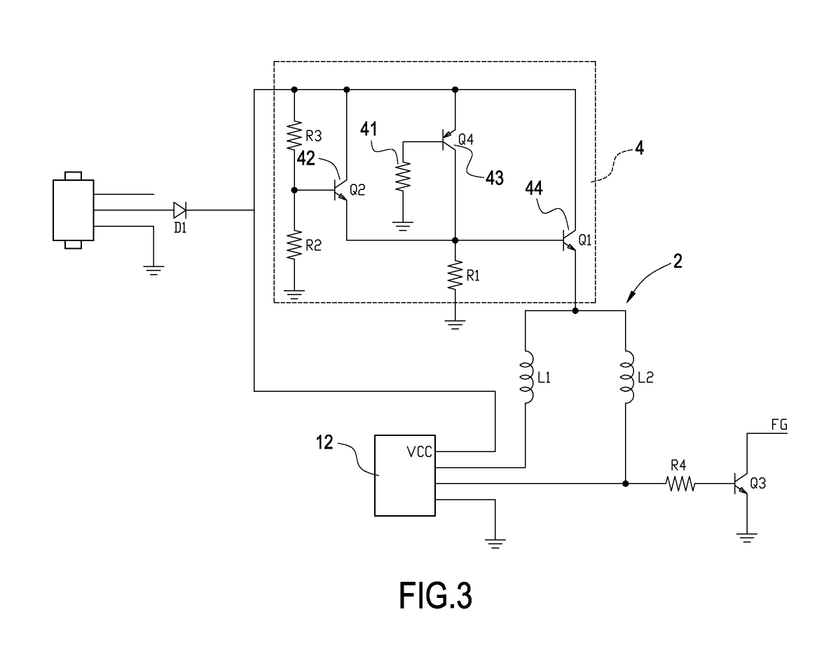

FIG. 2 is schematic illustrating the architecture of a simple temperature control device in a half-wave configuration according to a preferred embodiment of the invention. FIG. 3 is a circuit schematic illustrating a simple temperature control device according to a preferred embodiment of the invention. As shown in FIGS. 2 and 3, the temperature control device of a simple cooling fan includes a fan motor 2, a driver device 3, and a temperature control device 4 collectively forming a simple, low-cost temperature control device as an external add-on of a cooling fan, allowing the overall size of the cooling fan to be manufactured less than 4 cm, and achieving temperature control capability near that of a MCU.

The coils L1 and L2 of the above described fan motor 2 are electrically connected to, and driven by, the driver device 3.

The output terminal of driver device 3 is connected to coils L1 and L2 of fan motor 2. Driver device 3 detects a rise in temperature of the electrical element and controls the amount of current being output to coils L1 and L2 from its own output terminal, so as to control the rotational speed of fan motor 2, particularly, to maintain at high rotational speed as the temperature of the electrical element increases.

Temperature control device 4 includes at least a sensor element 41, a first, second and third electronic switch (transistor) 42, 43 and 44, and a plurality of resistive elements R1, R2, and R3 to collectively to form a circuit. The parallelly connected resistive elements R2 and R3 together with the first electronic switch 42 form a lowest-rotational-speed temperature-setting-value circuit. Preferably, the lowest temperature is set to 30-42° C. Sensor element 41 is realized by any one of the following: a thermistor, a heat coupler, or a semiconductor element. Sensor element 41 is connected to second electronic switch 42, and changes the flow of a current I_{B} of the second electronic switch 43 when sensor element 41 detects a temperature drop of the electrical element (not shown). When current I_{B}is altered, so does current Ic, which consequently generates a voltage drop across the voltage-drop generation circuit RI. The voltage drop then turns on third electronic switch 44 for controlling fan motor 2 in reducing its rotational speed to match the current temperature level of the electrical element.

The temperature control device 4, applied in a cooling fan, effectively allows the physical size of the cooling fan to be reduced, to less than 4 cm, thereby satisfying the current trend for compact designs. Also, by making appropriate rotational speed adjustment in correspondence with the temperature variation, the invention achieves control efficiency close to that of a higher-cost MCU.

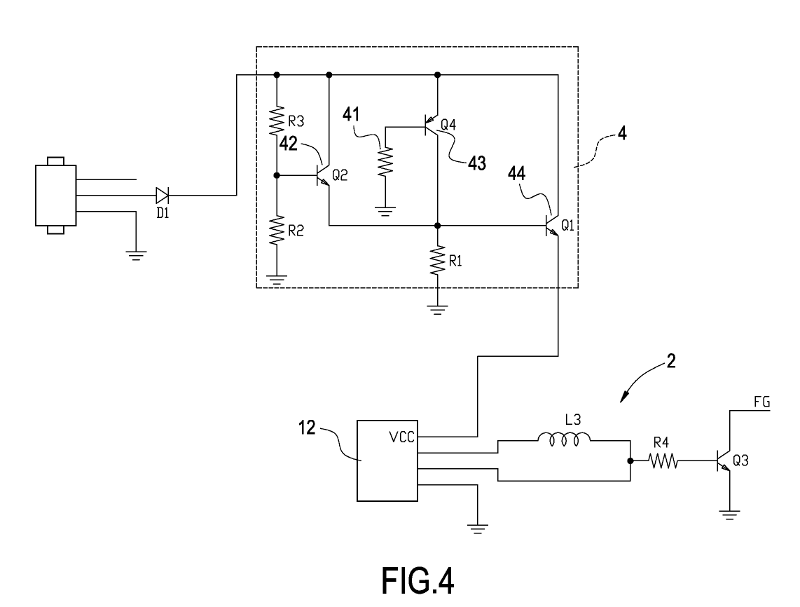

FIG. 4 is circuit schematic illustrating a temperature control device of a cooling fan according to a preferred embodiment of the invention applied in a full-wave configuration. As shown in the figure, the current embodiment is similar to the embodiments shown in FIGS. 2 and 3, and differs in that the coil L3 of fan motor 2 is in a full-wave configuration connected to temperature control device 4. Thus, as previous embodiments, the temperature control device 4 can be controlled to output a voltage-drop signal to trigger fan motor 2 to reduce its rotational speed based on the temperature drop variation of the electronic element detected by temperature control circuit 4, and thereby successfully providing user with a more compact, and cheap temperature control device for application in a cooling fan that achieves control capabilities close to that of a higher-cost MCU.

Although the present invention has been explained in relation to its preferred embodiment, it is to be understood that many other possible modifications and variations can be made without departing from the spirit and scope of the invention as hereinafter claimed.

What is claimed is:

1. A temperature control device of a simple cooling fan, comprising:
a fan motor;
a driver device connected to the fan motor; and
a temperature control device connected to the fan motor and the driver device;
wherein the temperature control device detects a temperature drop variation of an electronic element, and outputs a voltage-drop signal to drive the fan motor to reduce rotational speed.

2. The temperature control device as claimed in claim 1, wherein the temperature control device includes:
a lowest-rotational-speed temperature-setting-value circuit;
a sensor circuit electrically connected to the lowest-rotational-speed temperature-setting-value circuit;
a second electronic switch electrically connected to the sensor circuit;
a voltage-drop generation circuit electrically connected to the lowest-rotational-speed temperature-setting-value circuit and the second electronic switch; and
a third electronic switch electrically connected to the second electronic switch and the voltage-drop generation circuit.

3. The temperature control device as claimed in claim 2, wherein the lowest-rotational- speed temperature-setting-value circuit is formed by resistive elements R2 and R3 and a first electronic switch, the first electronic switch being parallelly connected to said resistive elements.

4. The temperature control device as claimed in claim 3, wherein the first electronic switch is a transistor element.

5. The temperature control device as claimed in claim 2, wherein the sensor element is a thermistor, a heat coupler, or a semiconductor element.

6. The temperature control device as claimed in claim 2, wherein the second and the third electronic switches are both transistor elements.

7. The temperature control device as claimed in claim 2, wherein the voltage-drop generation circuit is formed by a resistor R1.

8. The temperature control device as claimed in claim 1, wherein the temperature control device is connected to a fan motor driver circuit in either a full-wave or a half-wave configuration.
